(19) United States
(12) Patent Application Publication
(10) Pub. No.: US 2025/0248156 A1
(43) Pub. Date: Jul. 31, 2025

(54) SEMICONDUCTOR DEVICE AND METHODS OF MANUFACTURING THE SAME

(71) Applicant: Taiwan Semiconductor Manufacturing Company, Ltd., Hsinchu (TW)

(72) Inventors: Yi-Hsuan WANG, Hsinchu City (TW); Cheng-Yu HUANG, Hsinchu (TW); Wei-Chieh CHIANG, Yuanlin Township (TW); Keng-Yu CHOU, Kaohsiung City (TW); Chun-Hao CHUANG, Hsinchu City (TW); Wen-Hau WU, New Taipei City (TW)

(21) Appl. No.: 18/428,020

(22) Filed: Jan. 31, 2024

(51) Int. Cl. H01L 27/146

(52) U.S. Cl. CPC H10F 39/8063; H10F 39/024; H10F 39/184; H10F 39/805; H10F 39/807

(57) ABSTRACT

Some implementations herein include a pixel sensor structure and methods of forming. The pixel sensor structure includes a lens structure, a photodiode sensor structure, and an optical spacer structure between the lens structure and the photodiode sensor structure. The lens structure redirects near infrared light through the optical spacer structure and to the photodiode sensor structure to improve the quantum efficiency performance of the photodiode sensor structure relative to another photodiode sensor structure include in a pixel sensor structure without the lens structure and the optical spacer structure. Additionally, different configurations of an anti-reflection coating layer may be included throughout the pixel sensor structure to improve the quantum efficiency performance of the photodiode sensor structure further.

### BACKGROUND

Complementary metal oxide semiconductor (CMOS) image sensors utilize light-sensitive CMOS circuitry to convert light energy into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

Light received by pixel sensors of a CMOS image sensor is often based on the three primary colors: red, green, and blue (R, G, B). Pixel sensors that sense light for each color can be defined through the use of a color filter that allows the light wavelength for a particular color to pass into a photodiode. Some pixel sensors may include a near infrared (NIR) pass filter, which blocks visible light and passes near infrared light through to the photodiode.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example pixel array described herein.

FIGS. 2A-2D are diagrams of example implementations of a pixel sensor structure described herein.

FIG. 3 is a diagram of an example implementation of a system including a pixel sensor structure described herein.

FIGS. 4A-4I are diagrams of an example series of semiconductor processing operations to form a pixel sensor structure described herein.

FIG. 5 is a flowchart an example process associated with forming a pixel sensor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A performance of a photodiode sensor structure included in a pixel sensor structure may be quantified in terms of quantum efficiency (QE). Quantum efficiency is expressed as a ratio or percentage and represents the efficiency with which photons of light are converted into photoelectrons (electrons generated by the absorption of photons) within the photodiode sensor structure. In other words, quantum efficiency quantifies how good a photodiode sensor structure is at turning incoming photons into usable electrical signals. Furthermore, quantum efficiency directly affects the sensitivity performance of the pixel sensor structure.

In some cases, the photodiode sensor structure may have an inherently low quantum efficiency for receiving and converting near infrared light (e.g., electromagnetic waves having wavelengths between approximately 700 nanometers (nm) to 2500 nm) to a photocurrent. To increase the quantum efficiency, the photodiode sensor structure may include a germanium single-photon avalanche photodiode (GeSPAD) sensor structure. Furthermore, the photodiode sensor structure may be surrounded by an isolation grid to reduce optical and/or electrical cross talk with an adjacent pixel sensor structure. However, such modifications may fail to significantly improve the quantum efficiency performance of the photodiode sensor structure and cause the pixel sensor structure to fail to satisfy a quantum efficiency performance threshold and/or a sensitivity performance threshold associated with an application configured to detect the near infrared light.

Some implementations herein include a pixel sensor structure and methods of forming. The pixel sensor structure includes a lens structure, a photodiode sensor structure, and a optical spacer structure between the lens structure and the photodiode sensor structure. The lens structure redirects near infrared light through the optical spacer structure and to the photodiode sensor structure to improve the quantum efficiency performance of the photodiode sensor structure relative to another photodiode sensor structure include in a pixel sensor structure without the lens structure and the optical spacer structure. Additionally, different configurations of an anti-reflection coating layer may be included throughout the pixel sensor structure to improve the quantum efficiency performance of the photodiode sensor structure further.

In this way, a quantum efficiency performance of the photodiode sensor structure and/or a sensitivity performance of the pixel sensor structure is increased to satisfy one or more performance thresholds related to an application that senses images in a low-lighting environment. By satisfying the one or more performance thresholds, an amount of resources supporting a volume of a market using the pixel sensor structure 200 (e.g., labor, raw materials, semiconductor processing tools, and/or computing resources that are consumed achieving a manufacturing yield that corresponds to the one or more performance thresholds) is reduced.

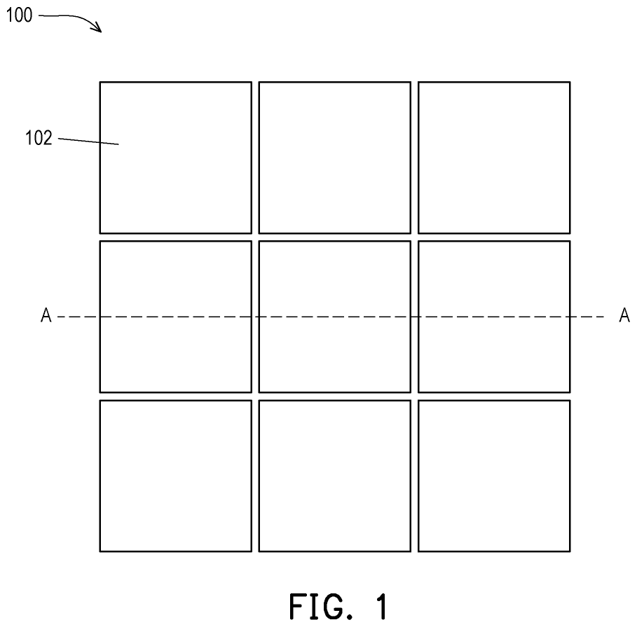

FIG. 1 is a diagram of an example pixel array 100 (or a portion thereof) described herein. The pixel array 100 may be included in an image sensor, such as a complementary metal oxide semiconductor (CMOS) image sensor, a back side illumination (BSI) CMOS image sensor, or another type of image sensor. In some implementations, the image sensor is an image sensor configured to detect near infrared light in a low-light application included in a surveillance system, a night vision system, or an automotive camera, among other examples.

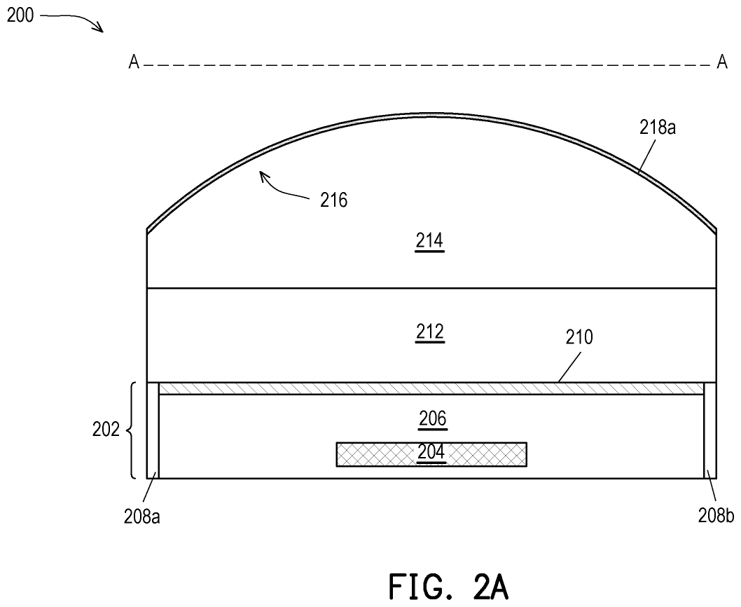

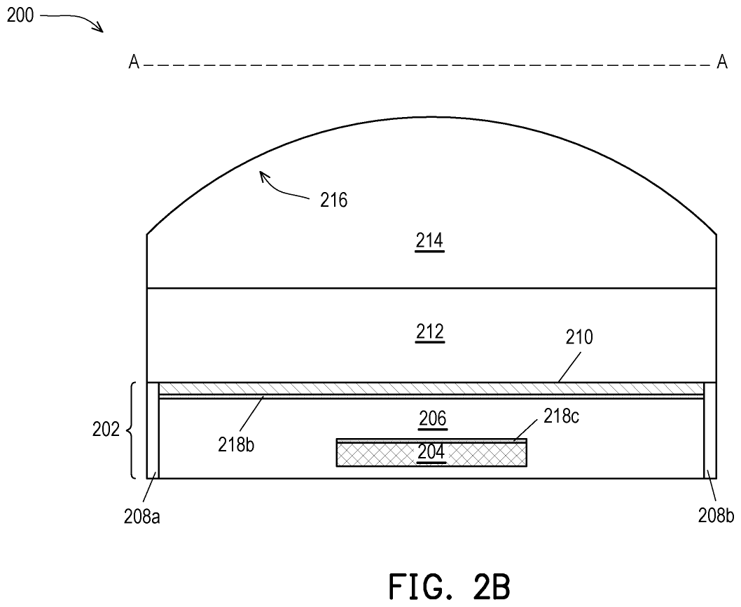

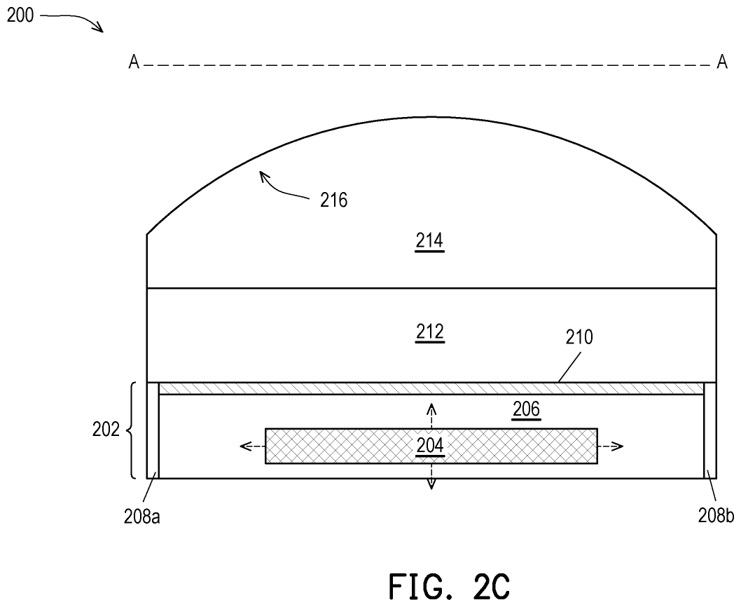

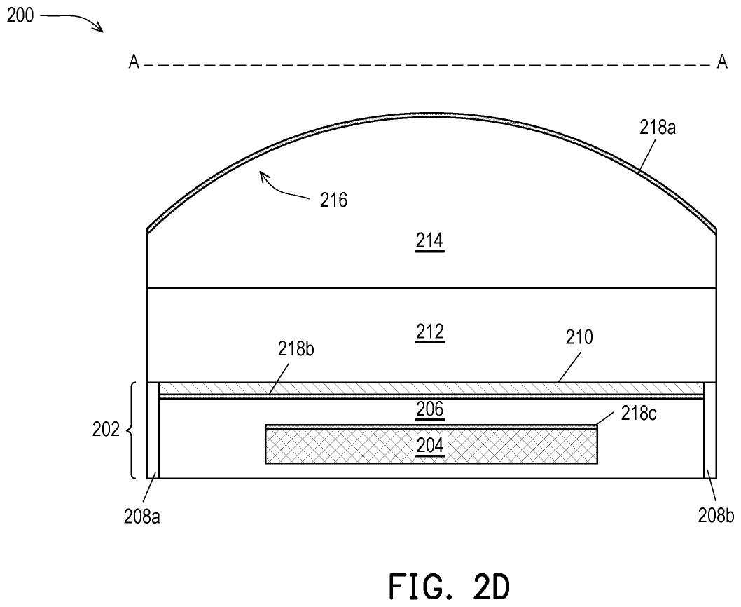

FIG. 1 shows a top-down view of the pixel array 100. As shown in FIG. 1, the pixel array 100 may include a plurality of pixel sensors 102. FIG. 1 further includes a section A-A that is used to illustrate side section views of pixel sensor structures in FIGS. 2A-4I, where the pixel sensor structures may correspond to one or more of the pixel sensors 102.

As further shown in FIG. 1, the pixel sensors 102 may be arranged in a grid. In some implementations, the pixel sensors 102 are square-shaped (as shown in the example in FIG. 2). In some implementations, the pixel sensors 102 include other shapes such as circle shapes, octagon shapes, diamond shapes, and/or other shapes.

The pixel sensors 102 may be configured to sense and/or accumulate incident light (e.g., light directed toward the pixel array 100). For example, a pixel sensor 102 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness).

In some implementations, the pixel array 100 may be electrically connected to an interconnect metallization stack (not shown) of the image sensor. The interconnect metallization stack may electrically connect the pixel array 100 to control circuitry that may be used to measure the accumulation of incident light in the pixel sensors 102 and convert the measurements to an electrical signal.

As described in greater detail in connection with FIGS. 2A-2D, 3, 4A-4I, and 5, one or more of the pixel sensor(s) 102 of the pixel array 100 may include a pixel sensor structure designed for detecting near infrared light. The pixel sensor structure may include one or more features such as a lens structure, a optical spacer structure, a photodiode sensor structure, and/or antireflective coating layers dispersed on one or more material interfaces within the pixel sensor structure. An arrangement of these features may guide the near infrared light through the pixel sensor structure and increase an amount of near infrared light (e.g., photons) absorbed by the photodiode sensor structure.

As indicated above, FIG. 1 is provided as an example. Other examples may differ from what is described with regard to FIG. 1.

FIGS. 2A-2D are diagrams of example implementations of a pixel sensor structure 200 described herein. The pixel sensor structure 200 may correspond to one or more of the pixel sensors 102 as described in connection with FIG. 1. Furthermore, FIGS. 2A-2D, 3, and 4A-4I illustrate the pixel sensor structure 200 using the section A-A of FIG. 1.

As shown in the example implementation of FIG. 2A, the pixel sensor structure 200 includes a photodiode region 202 that includes a photodiode sensor structure 204 in a semiconductor layer 206 (e.g., the photodiode sensor structure 204 is embedded in the semiconductor layer 206). The photodiode sensor structure 204 includes a region that is doped with a plurality of types of ions to form a p-n junction or a PIN junction (e.g., a junction between a p-type portion, an intrinsic (or undoped) type portion, and an n-type portion). For example, an ion implantation device tool may be used to implant an n-type dopant to form a first portion (e.g., an n-type portion) of a photodiode and a p-type dopant to form a second portion (e.g., a p-type portion) of the photodiode. The photodiode sensor structure 204 may be configured to absorb photons of incident light. The absorption of photons causes the photodiode sensor structure 204 to accumulate a charge (referred to as a photocurrent) due to the photoelectric effect. Here, photons bombard the photodiode region 202, which causes emission of electrons from photodiode sensor structure 204. The emission of electrons causes the formation of electron-hole pairs, where the electrons migrate toward a cathode of the photodiode sensor structure 204, and the holes migrate toward an anode, which produces the photocurrent.

In some implementations, the photodiode sensor structure 204 corresponds to a single-photon avalanche photodiode structure that has a capability to detect individual photons (e.g., the smallest units of light) with a sensitivity and precision that enables detection of near infrared light. In such implementations, the photodiode sensor structure 204 may utilize an avalanche effect to amplify an electrical signal generated by individual photons. As part of the avalanche effect, an individual photon may strike the photodiode sensor structure 204 and create an electron-hole pair. An electric field within the photodiode sensor structure 204 may accelerate these charge carriers, leading to impact ionization, which generates additional electron-hole pairs, resulting in an avalanche of charge carriers and an amplified output signal.

To enable the avalanche effect, the photodiode sensor structure 204 may include a combination of one or more type III-V chemical elements or materials having a bandgap energy level that is suitable for enabling the avalanche effect. As an example, the photodiode sensor structure 204 may include germanium (Ge), in which case the photodiode sensor structure 204 may be referred to as a germanium single-photon avalanche (GeSPAD) structure. Alternatively, the photodiode sensor structure 204 may include gallium arsenide (GaAs) or indium gallium arsenide (InGaAs), among other examples.

The semiconductor layer 206 may include a semiconductor material suitable for forming integrated circuit devices (e.g., transistors, amplifiers, analog-to-digital converters, signal processors, logic) that might be included in a semiconductor device including the photodiode sensor structure 204. As an example, the semiconductor material may include silicon (Si), in which case the semiconductor layer 206 may be referred to as a silicon layer. Alternatively, the semiconductor material may include gallium arsenide (GaAs), indium gallium arsenide (InGaAs), amorphous silicon (a-Si), or silicon carbide (SiC), among other examples.

As further shown in FIG. 2A, the photodiode region 202 further includes an isolation structure 208a, an isolation structure 208b, and a multi-layer structure 210. As shown in FIG. 2A, the isolation structure 208a and isolation structure 208b are on opposite sides of the photodiode sensor structure 204. As further shown in FIG. 2A, the multi-layer structure 210 is on a surface of the semiconductor layer 206.

In some implementations, the isolation structure 208a and isolation structure 208b are included in a grid layout that extends around a perimeter of the pixel sensor structure 200. The isolation structure 208a and the isolation structure 208b (e.g., deep trench backside isolation structures) may provide optical isolation by blocking or preventing diffusion or bleeding of light from pixel sensor structure 200 to adjacent pixel sensor structures, thereby reducing optical crosstalk. Additionally, or alternatively, the isolation structure 208a and the isolation structure 208b may provide electrical isolation by reducing a likelihood of exchanging charge carriers (e.g., electrons or electron holes) with adjacent pixel sensor structures, thereby reducing electrical crosstalk. In some implementations, the isolation structure 208a and/or the isolation structure 208b include a dielectric material such as silicon dioxide (SiO2), silicon nitride (SiN), or another suitable dielectric material, among other examples.

The multi-layer structure 210 may include one or more layers of an electrically conductive material used for integrated circuit devices on or within the semiconductor layer 206. In some implementations the electrically conductive material may be a transparent conductive oxide material that is transmissive to near infrared light, such as indium tin oxide (ITO), among other examples. Additionally, or alternatively, the multi-layer structure 210 may include one or more layers of a dielectric material to isolate and/or separate the one or more layers of the electrically conductive material. In some implementations, the dielectric material is a dielectric material that is transmissive to near infrared light, such as silicon dioxide (SiO₂) or aluminum dioxide (Al₂O₃), among other examples.

As shown in FIG. 2A, an optical spacer structure 212 is above the photodiode region 202. In some implementations, the optical spacer structure 212 is on the multi-layer structure 210. The optical spacer structure 212 may include a polymer material that is transmissive to near infrared light, such as polymethyl methacrylate (PMMA), polycarbonate, polyethylene (PE), polyvinylidene fluoride (PVDF), or another suitable polymer material, among other examples. Alternatively, the optical spacer structure 212 may include a resin material that is transmissive to infrared light, such as epoxy resin or another suitable resin material, among other examples. Alternatively, the optical spacer structure 212 may include an organic material that is transmissive to near infrared light, such as a cyclo-olefin copolymer (COC), cyclo-olefin polymer (COP), or another suitable organic material, among other examples.

As shown in FIG. 2A, a lens structure 214 having a convex surface 216 is above the optical spacer structure 212. The convex surface 216 has a substantially convex curvature that extends away from the optical spacer structure 212 and/or the photodiode sensor structure 204. In some implementations, the lens structure 214 is on the optical spacer structure 212. The lens structure 214 may include a polymer material that is transmissive to near infrared light, such as polymethyl methacrylate (PMMA), polycarbonate, polyethylene (PE), polyvinylidene fluoride (PVDF), or another suitable polymer material, among other examples. Alternatively, the lens structure 214 may include a resin material that is transmissive to near infrared light, such as epoxy resin or another suitable resin material, among other examples. Alternatively, the lens structure 214 may include an organic material that is transmissive to near infrared light, such as a cyclo-olefin copolymer (COC), cyclo-olefin polymer (COP), or another suitable organic material, among other examples.

As shown in FIG. 2A, the optical spacer structure 212 is between the lens structure 214 and the photodiode sensor structure 204. In some implementations, the optical spacer structure 212 is configured to maintain a separation distance between a between a bottom surface of the lens structure 214 and a top surface of the photodiode region 202 including the photodiodes sensor structure 204. The separation distance may alter a focal length of the lens structure 214 and optimizes a dispersion of light across a surface of the photodiode sensor structure 204.

As shown in FIG. 2A, an anti-reflective coating layer 218a is on the convex surface 216. The anti-reflective coating layer 218a may include a material that reduces reflectance of near infrared light from the convex surface 216 and promote a transmission of near infrared light through the lens structure 214. Reducing the reflectance of near infrared light and promoting the transmission of near infrared light through the lens structure 214 may increase a photon absorption by the photodiode sensor structure 204. Examples of such a material include an oxide material such as tantalum pentoxide (T₂O₅) or another suitable material that reduces the reflectance of near infrared light, among other examples.

FIG. 2B shows another example implementation of the pixel sensor structure 200. In FIG. 2B, and in contrast to the implementation of FIG. 2A having the anti-reflective coating layer 218a on the convex surface 216, the pixel sensor structure 200 includes the anti-reflective coating layer 218b on the semiconductor layer 206 and the anti-reflective coating layer 218c on the photodiode sensor structure 204.

FIG. 2C shows another example implementation of the pixel sensor structure 200. In FIG. 2C, and relative to implementations of FIG. 2A and/or FIG. 2B, a width of the photodiode sensor structure 204 may be increased to enlarge an effective area of the photodiode sensor structure 204 for receiving photons to improve a quantum efficiency performance of the photodiode sensor structure 204. Additionally, or alternatively and relative to implementations of FIGS. 2A and 2B, a thickness of the photodiode sensor structure 204 may be increased to improve a sensitivity performance of the photodiode sensor structure 204.

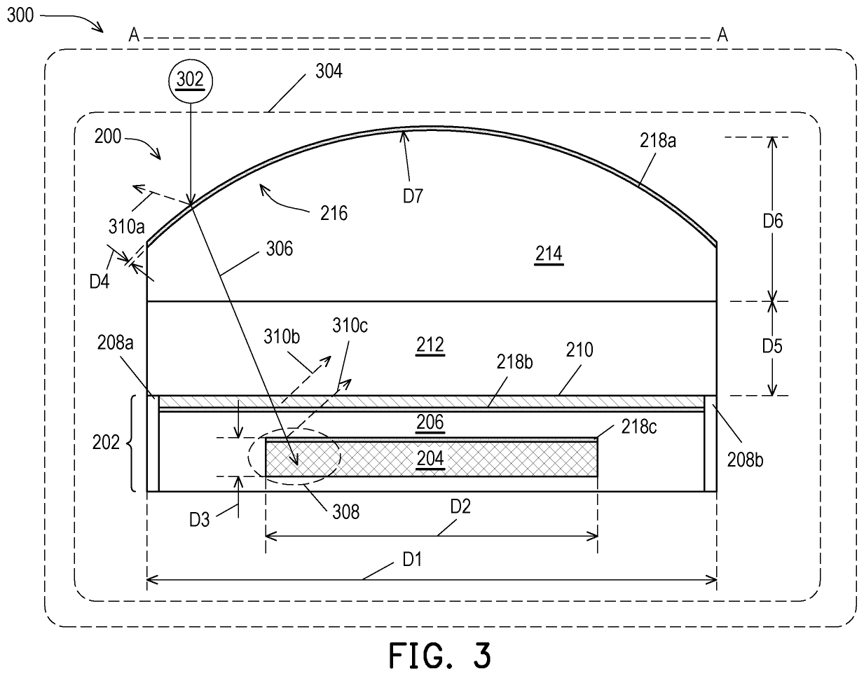

FIG. 2D shows another example implementation of the pixel sensor structure 200, in which features described in connection with FIGS. 2A-2C (e.g., the increased thickness/width of the photodiode sensor structure 204, the optical spacer structure 212, the lens structure 214, the convex surface 216, and the anti-reflective coating layers 218a-218c) are combined. As described in greater detail in connection with FIG. 3, different features may be selected and/or combined based on performance thresholds related to an image sensing application used in a low-lighting environment (e.g., an image sensing application detecting near infrared light). Additionally, or alternatively and as described in greater detail in connection with FIG. 3, combinations of geometric properties and/or materials associated with the features may be selected and/or varied to “tune” a performance of the pixel sensor structure 200 and satisfy a performance threshold of a device or system including the pixel sensor structure 200.

As described in connection with FIGS. 2A-2D, implementations of a pixel sensor structure (e.g., the pixel sensor structure 200) include a photodiode region (e.g., the photodiode region 202) having a photodiode sensor structure (e.g., the photodiode sensor structure 204) in a semiconductor layer (e.g., the semiconductor layer 206). The pixel sensor structure includes a lens structure (e.g., the lens structure 214) apart from the photodiode sensor region and having a substantially convex surface (e.g., the convex surface 216 having the substantially convex curvature) facing away from the photodiode region. The pixel sensor structure includes an optical spacer structure (e.g., the optical spacer structure 212). In some implementations, the optical spacer structure is configured to maintain a separation distance between a bottom of the lens structure and a top of the photodiode region.

The number and arrangement of structures shown in FIGS. 2A-2D are provided as one or more examples. In practice, there may be additional structures, fewer structures, different structures, or differently arranged structures than those shown in FIGS. 2A-2D. Furthermore, two or more structures shown in FIGS. 2A-2D may be implemented within a single device, or a single structure shown in FIGS. 2A-2D may be implemented as multiple, distributed devices. Additionally, or alternatively, a set of structures (e.g., one or more structures) may perform one or more functions described as being performed by another set of structures.

FIG. 3 is a diagram of an example implementation of a system 300 including a pixel sensor structure described herein (e.g., the pixel sensor structure 200). In some implementations, the system 300 may be a system used in a low-lighting application such as a surveillance system, a night vision system, or an automotive camera system, among other examples. As shown in FIG. 3, the system may include a light source 302 (e.g., a near infrared light source). Additionally, or alternatively and as shown in FIG. 3, the pixel sensor structure 200 may be included as part of an image sensor device 304 (e.g., a complementary metal oxide semiconductor (CMOS) image sensor, a back side illumination (BSI) CMOS image sensor device, or another type of image sensor device).

In FIG. 3, the photodiode sensor structure 204 receives light 306 that is projected by the light source 302 (e.g., near infrared light reflected from a target to be imaged by the system 300). The light 306 may be redirected by the convex surface 216 of the lens structure 214 to the photodiode sensor structure 204 along a path through the lens structure 214, the optical spacer structure 212, the multi-layer structure 210, and a portion of the semiconductor layer 206.

As shown in FIG. 3, the pixel sensor structure 200 includes a width D1 and the photodiode sensor structure 204 includes a width D2. The width D1 (e.g., a size of the pixel sensor structure 200) may be included in a range of approximately 9 microns (μm) to approximately 11 μm, among other examples. Based on the width D1, and as described in connection with FIG. 2C, the width D2 may be selected and/or increased to a width that does not exceed the width D1 and/or interfere with the isolation structure 208a and/or the isolation structure 208b (e.g., the width D2 may be included in a range of approximately 7 μm to approximately 9 μm). By increasing the width D2, an extension region 308 of the photodiode sensor structure 204 may be formed to increase an effective area of the photodiode sensor structure 204 and receive additional light (e.g., photons of the light 306). Selecting a width D2 that exceeds the width D1 may prevent miniaturization of the pixel sensor structure 200. Additionally, or alternatively, selecting a width D2 that interferes with the isolation structure 208a and/or the isolation structure 208b may reduce an effectiveness of the isolation structure 208a and/or the isolation structure 208b (e.g., reduce effectiveness of the isolation structure 208a and/or the isolation structure 208b providing electrical and/or optical isolation of the pixel sensor structure 200 from other, adjacent pixel structures). However, other values and/or ranges for the widths D1 and D2 are within the scope of the present disclosure.

As further shown in FIG. 3, the photodiode sensor structure 204 includes a thickness D3. As described in connection with FIG. 2C, the thickness D3 may be selected and/or increased to improve a capability of the photodiode sensor structure 204 to detect the light 306 in the photodiode sensor structure 204 (e.g., detect photons in the sensing region 308) and satisfy a quantum efficiency performance threshold. As an example, the thickness D3 may be selected and/or increased such that thickness D3 is greater than or equal to approximately 3 μm to increase detectability of the photons and enable the photodiode sensor structure 204 satisfy the quantum efficiency performance threshold. Selecting and/or decreasing the thickness D3 to less than approximately 3 μm may decrease the detectability of the photons and cause the photodiode sensor structure 204 to fail to satisfy the quantum efficiency performance threshold. However, other values and/or ranges for the thickness D3 are within the scope of the present disclosure.

As shown in FIG. 3, the anti-reflective coating layer 218a is on the convex surface 216 and in a path of the light 306 between the light source 302 and the photodiode sensor structure 204. In some implementations, the anti-reflective coating layer 218a reduces and/or eliminates a reflection 310a of the light 306 from the convex surface 216 to reduce losses and improve an amount the light 306 transmitted through the lens structure 214.

As shown in FIG. 3, the anti-reflective coating layer 218b is on the semiconductor layer 206 and in the path of the light 306 between the light source 302 and the photodiode sensor structure 204. In some implementations, the anti-reflective coating layer 218b reduces and/or eliminates the reflection 310b from the semiconductor layer 206 to reduce losses and improve an amount the light 306 transmitted through the optical spacer structure 212.

As shown in FIG. 3, the anti-reflective coating layer 218c is on the photodiode sensor structure 204 and in the path of the light 306 between the light source 302 and the photodiode sensor structure 204. In some implementations, the anti-reflective coating layer 218c reduces and/or eliminates the reflection 310c from the photodiode sensor structure 204 to reduce losses and improve an amount the light 306 absorbed by the photodiode sensor structure 204.

In some implementations, a thickness D4 of the anti-reflective coating layer 218a, the anti-reflective coating layer 218b, and/or the anti-reflective coating layer 218c may be selected based on a material included in the anti-reflective coating layer 218a, the anti-reflective coating layer 218b, and/or the anti-reflective coating layer 218c and a type of light for which reflectance is to be reduced. For example, for a case in which the anti-reflective coating layer 218a, the anti-reflective coating layer 218b, and/or the anti-reflective coating layer 218c includes tantalum pentoxide material and the light 306 is near infrared light, the thickness D4 may be included in a range of approximately 0.1 μm to approximately 0.4 μm. Selecting the thickness D4 to be less than approximately 0.1 μm may cause the anti-reflective coating layer 218a, the anti-reflective coating layer 218b, and/or the anti-reflective coating layer 218c to be ineffective in reducing and/or eliminating the reflections of the light 306 (e.g., the reflections 310a, 310b, and/or 310c) and significantly reduce an amount of the light 306 transmitted through the lens structure 214, the optical spacer structure 212, and/or the semiconductor layer 206 to the photodiode sensor structure 204. Selecting the thickness D4 to be between approximately 0.1 μm and 0.4 μm may enable the anti-reflective coating layer 218a, the anti-reflective coating layer 218b, and/or the anti-reflective coating layer 218c to be effective in reducing and/or eliminating the reflections of the light 306 and maintain a transmissivity that does not significantly reduce the amount of the light 306 transmitted through the lens structure 214, the optical spacer structure 212, and/or the semiconductor layer 206 to the photodiode sensor structure 204. Selecting the thickness D4 to be greater than 0.4 μm may cause the anti-reflective coating layer 218a, the anti-reflective coating layer 218b, and/or the anti-reflective coating layer 218c to be opaque and reduce the amount of the light 306 transmitted through the lens structure 214, the optical spacer structure 212, and/or the semiconductor layer 206 to the photodiode sensor structure 204. However, other combinations of materials for the anti-reflective coating layer 218a, the anti-reflective coating layer 218b, and/or the anti-reflective coating layer 218c, values and ranges for the thickness D4, and types of light are within the scope of the present disclosure.

As shown in FIG. 3, the optical spacer structure includes a thickness D5. The thickness D5 provides a separation distance between a bottom of the lens structure 214 and a top of the photodiode region 202. As further shown in FIG. 3, the lens structure 214 includes the thickness D6. As examples, the thickness D5 may be included in a range of approximately 5 μm to approximately 8 μm and the thickness D6 may be included in a range of approximately 3 μm to approximately 8 μm. In some implementations, the thickness D5 and D6 are selected based on a size of the pixel sensor structure 200 (e.g., the width D1).

As shown in FIG. 3, the convex surface 216 includes a radius of curvature D7. In some implementations, that radius of curvature D7 may be based on the width D2 of the photodiode sensor structure 204 in combination with an offset of the convex surface 216 from the photodiode sensor structure 204, where the offset is a biproduct of the thickness D5 and the thickness D6. As an example, and for a case in which the width is D2 is an increased width included in a range of approximately 7 μm to approximately 9 μm, the thickness D5 is included in the range of approximately 5 μm to approximately 8 μm, and the thickness D6 is included in a range of approximately 3 μm to approximately 8 μm, a ratio of the radius of curvature D7 to the width D2 (D7:D2) may be included in a range of approximately 2:5 to approximately 3:5.

Selecting the ratio D7:D2 to be less than approximately 2:5 may cause the light 306 that is passing through the lens structure 214, the optical spacer structure 212, and the semiconductor layer 206 to converge in an area of the photodiode sensor structure 204 that is substantially less than an available area of the photodiode sensor structure 204 to reduce a quantum efficiency performance of the photodiode sensor structure 204 and cause the pixel sensor structure 200 to fail to satisfy a quantum efficiency performance threshold. Additionally, or alternatively, selecting the ratio D7:D2 to be less than approximately 2:5 may result in an inefficient use of materials that form the pixel sensor structure 200. Selecting the ratio D7:D2 to be between approximately 2:5 and approximately 3:5 may cause the light 306 that is passing through the lens structure 214, the optical spacer structure 212, and the semiconductor layer 206 to converge in an area of the photodiode sensor structure 204 that is approximately equal to the available area of the 204 to increase the quantum efficiency performance of the photodiode sensor structure 204 and cause the photodiode sensor structure 204 to satisfy the quantum efficiency performance threshold. Additionally, or alternatively, selecting the ratio D7:D2 to be between approximately 2:5 and approximately 3:5 may result in an efficient use of materials that form the pixel sensor structure 200. Selecting the ratio D7:D2 to be between greater than approximately 3:5 may cause the light 306 that is passing through the lens structure 214, the optical spacer structure 212, and the semiconductor layer 206 to converge in an area that substantially exceeds the available area of the photodiode sensor structure 204 to decrease a quantum efficiency performance of the photodiode sensor structure 204 and cause the photodiode sensor structure 204 to fail satisfy the quantum efficiency performance threshold. Additionally, or alternatively, selecting the ratio D7:D2 to be between greater than approximately 3:5 may result in an inefficient use of materials that form the pixel sensor structure 200 and/or prevent miniaturization of the pixel sensor structure 200. However, other values and ranges for the ratio D7:D2 are within the scope of the present disclosure.

As described in connection with FIGS. 2A-2D and 3, an implementation of a system (e.g., the system 300) includes an image sensor device (e.g., the image sensor device 304) including a pixel sensor structure (e.g., the pixel sensor structure 200). The pixel sensor structure include a lens structure (e.g., the lens structure 214), a single-photon avalanche photodiode structure (e.g., the photodiode sensor structure 204), a multi-layer structure (e.g., the multi-layer structure 210) having an electrically conductive material that is transmissive to near infrared light between the lens structure and the single-photon avalanche photodiode structure, and at least one anti-reflective coating layer (e.g., the anti-reflective coating layer 218a, the anti-reflective coating layer 218b, and/or the anti-reflective coating layer 218b) in a near infrared light path between a near infrared light source (e.g., the light source 302) and the single-photon avalanche photodiode structure.

As indicated above, FIG. 3 is provided as an example. Other examples may differ from what is described with regard to FIG. 3.

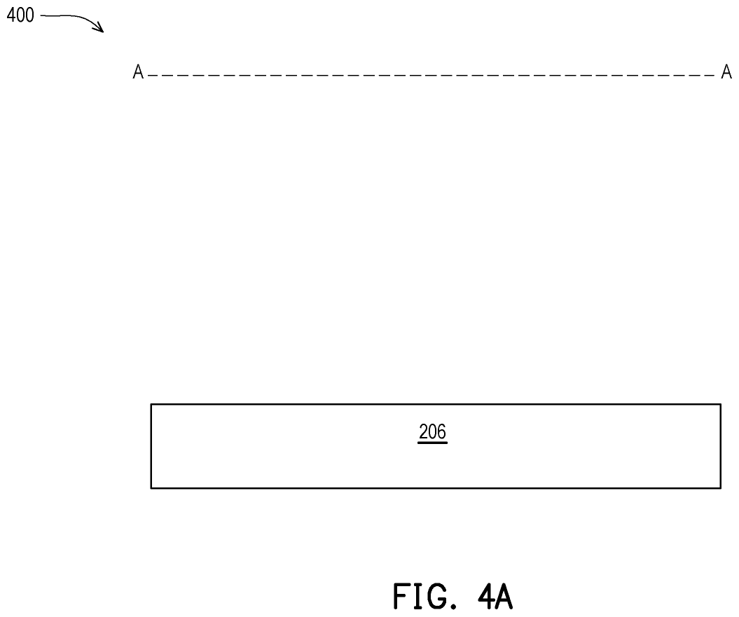

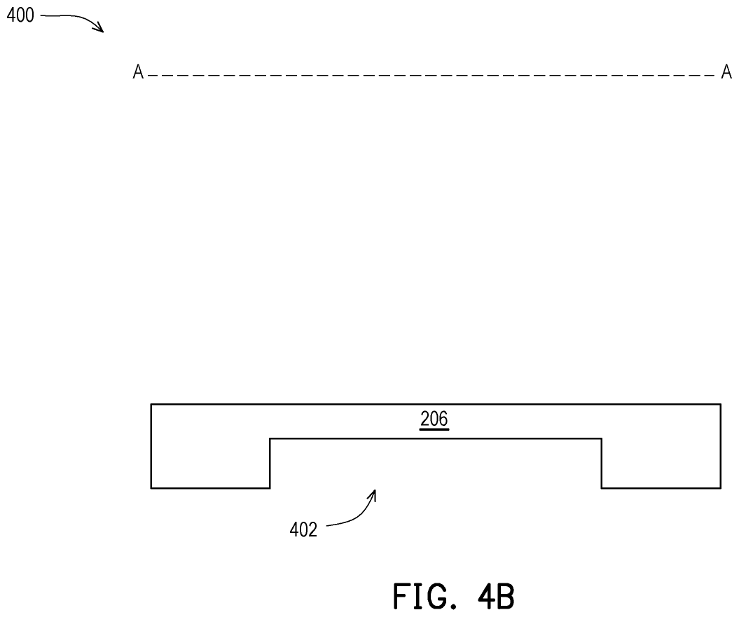

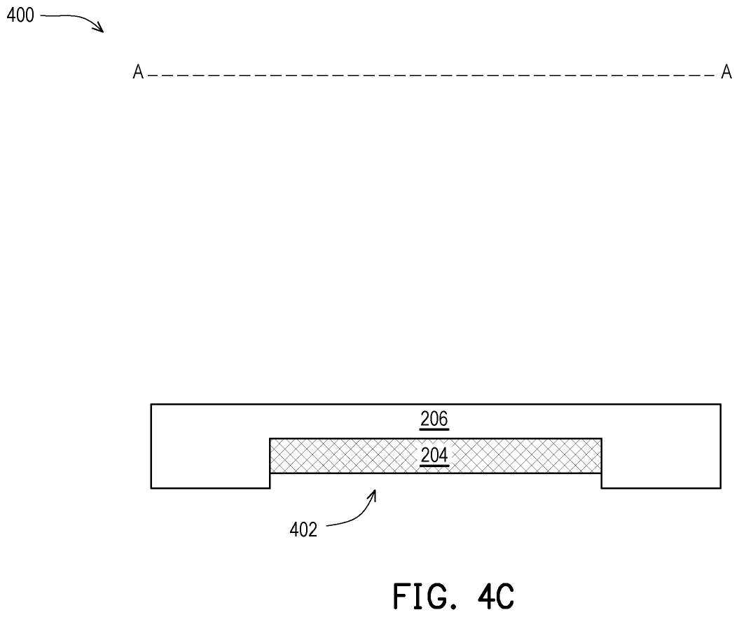

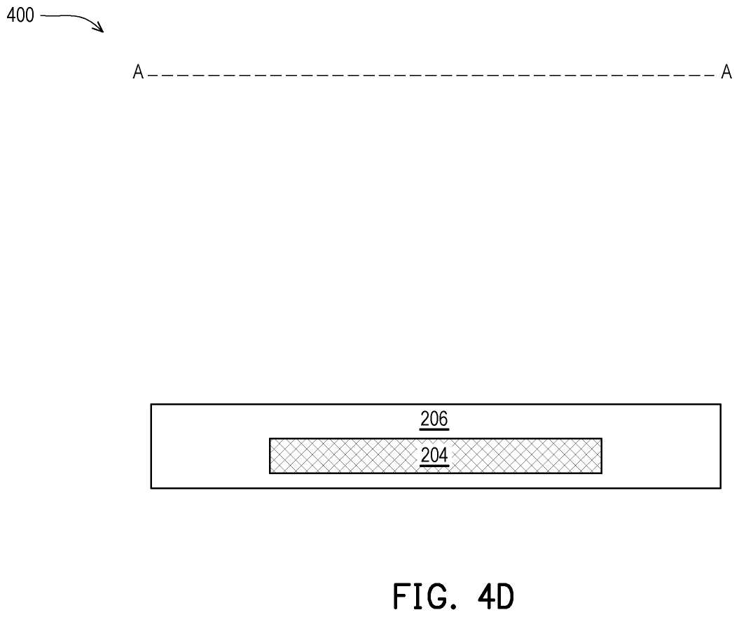

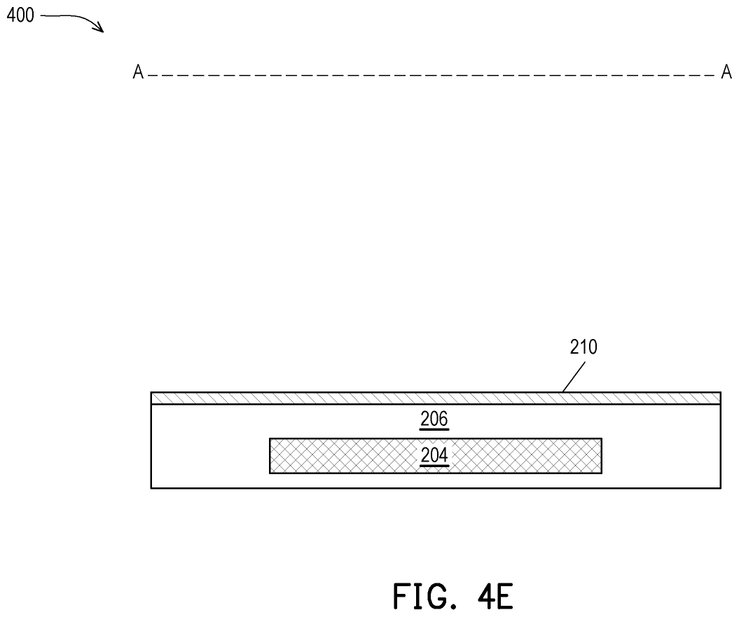

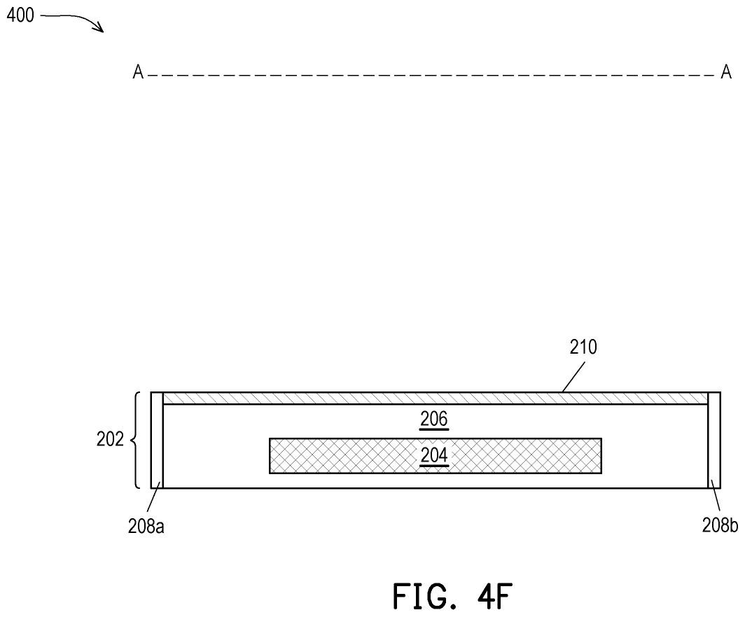

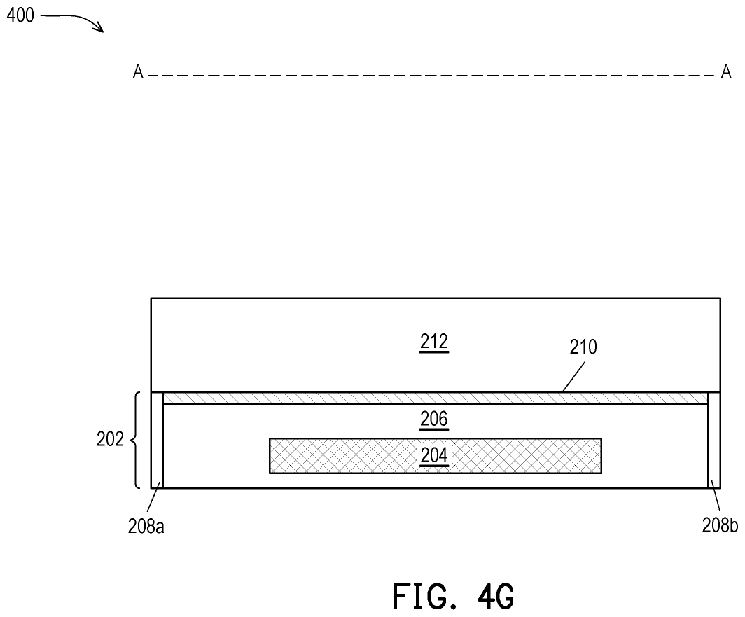

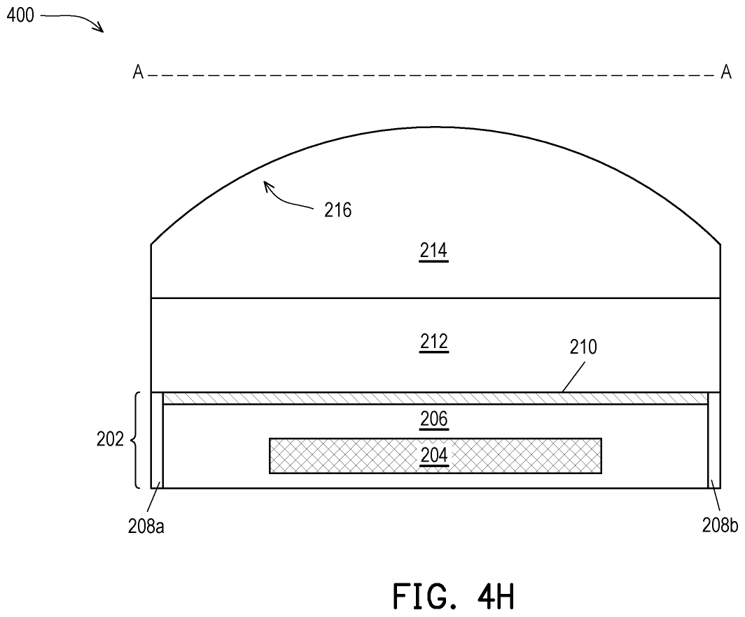

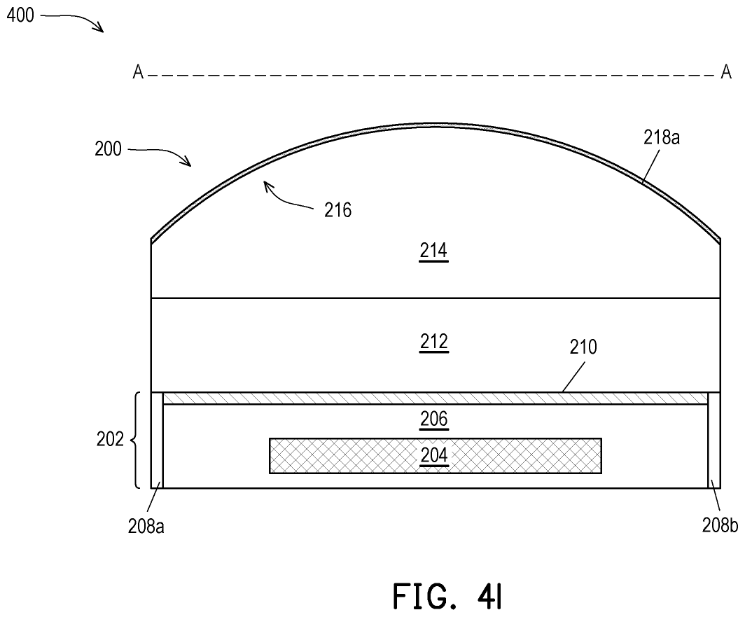

FIGS. 4A-4I are diagrams of an example series of semiconductor processing operations 400 to form a pixel sensor structure described herein (e.g., the pixel sensor structure 200). The series of semiconductor processing operations 400 may be performed by one or more semiconductor processing using a combination of deposition techniques, lithography techniques, and/or etching techniques to form the pixel sensor structure.

As shown in FIG. 4A, the series of semiconductor processing operations 400 includes providing the semiconductor layer 206. As an example, a wafer/die transport tool may be used to provide the semiconductor layer 206. In some implementations, the semiconductor layer 206 is provided on a temporary carrier or substrate (a ceramic carrier, a silicon substrate, or a gallium nitride (GaN) substrate, among other examples).

As shown in FIG. 4B, the series of semiconductor processing operations 400 includes forming a cavity 402 in the semiconductor layer 206. In some implementations, a pattern in a photoresist layer is used to etch the semiconductor layer 206 to form the cavity 402. In these implementations, a deposition tool may be used to form the photoresist layer on the semiconductor layer 206. An exposure tool may be used to expose the photoresist layer to a radiation source to pattern the photoresist layer. A developer tool may be used to develop and remove portions of the photoresist layer to expose the pattern. An etch tool may be used to etch the 206 based on the pattern to form the cavity 402 in the semiconductor layer 206. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 206 based on a pattern.

As shown in FIG. 4C, the series of semiconductor processing operations 400 includes forming the photodiode sensor structure 204 in the cavity 402. A deposition tool may be used to deposit the photodiode sensor structure 204 in an epitaxial growth operation. Alternatively, a deposition tool may be used to deposit the photodiode sensor structure 204 in a physical vapor deposition operation, an atomic layer deposition operation, a chemical vapor deposition operation, an oxidation operation, and/or another suitable deposition operation.

As shown in FIG. 4D, the series of semiconductor processing operations 400 includes forming a portion of the semiconductor layer 206 over and/or on the photodiode sensor structure 204. A deposition tool may be used to deposit the portion of the semiconductor layer 206 in an epitaxial growth operation. Alternatively, a deposition tool may be used to deposit the portion of the 206 in a physical vapor deposition operation, an atomic layer deposition operation, a chemical vapor deposition operation, an oxidation operation, and/or another suitable deposition operation.

As shown in FIG. 4E, the series of semiconductor processing operations 400 includes forming the multi-layer structure 210 over and/or on the semiconductor layer 206. A deposition tool may be used to deposit one or more layers of the multi-layer structure 210 in a physical vapor deposition operation, an atomic layer deposition operation, a chemical vapor deposition operation, an electroplating operation, and/or another suitable deposition operation. In some implementations, a planarization tool is used to planarize one or more layers of the multi-layer structure 210 after deposition.

As shown in FIG. 4F, the series of semiconductor processing operations includes forming the isolation structure 208a and the isolation structure 208b in the semiconductor layer 206. In some implementations, and to form the isolation structure 208a and/or the isolation structure 208b, a photoresist layer is used to etch the semiconductor layer 206 to form a cavity for the isolation structure 208a and/or the isolation structure 208b. In these implementations, a deposition tool may be used to form the photoresist layer on the semiconductor layer 206. An exposure tool may be used to expose the photoresist layer to a radiation source to pattern the photoresist layer. A developer tool may be used to develop and remove portions of the photoresist layer to expose the pattern. An etch tool may be used to etch the semiconductor layer 206 based on the pattern to form the cavity for the isolation structure 208a and/or the isolation structure 208b. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 206 based on a pattern.

Further, and as part of forming the isolation structure 208a and the isolation structure 208b in the semiconductor layer 206, a deposition tool may be used to deposit the isolation structure 208a and/or the isolation structure 208b in the cavities in a physical vapor deposition operation, an atomic layer deposition operation, a chemical vapor deposition operation, and/or another suitable deposition operation. In some implementations, a planarization tool may be used to planarize the isolation structure 208a and/or the isolation structure 208b after deposition.

As shown in FIG. 4G, the series of semiconductor processing operations 400 includes forming the optical spacer structure 212 over and/or on the multi-layer structure 210. A deposition tool may be used to deposit the optical spacer structure 212 in a spin-coating operation. Alternatively, a deposition tool may be used to deposit the optical spacer structure 212 in a physical vapor deposition operation, an atomic layer deposition operation, a chemical vapor deposition operation, and/or another suitable deposition operation. In some implementations, a planarization tool is used to planarize the optical spacer structure 212 after deposition.

As shown in FIG. 4H, the series of semiconductor processing operations 400 includes forming the lens structure 214 over and/or on the optical spacer structure 212. A deposition tool may be used to deposit a material used for the lens structure 214 using a spin coating-operation. Alternatively, a deposition tool may be used to deposit a material used for the lens structure in a physical vapor deposition operation, an atomic layer deposition operation, a chemical vapor deposition operation, and/or another suitable deposition operation. Further, and as part of forming the lens structure 214 over and/or on the optical spacer structure 212, a reflow tool may be used to heat the material, reflow the material, and form the convex surface 216.

As shown in FIG. 4I, the series of semiconductor processing operations includes forming the anti-reflective coating layer 218a over and/or on the lens structure 214. A deposition tool may be used to deposit the anti-reflective coating layer 218a in a physical vapor deposition operation, an atomic layer deposition operation, a chemical vapor deposition operation, an oxidation operation, and/or another suitable deposition operation.

As described in connection with FIGS. 2A-2D, 3, and 4A-4I, a series of semiconductor processing operations (e.g., the series of semiconductor processing operations 400) used to form a pixel sensor structure (e.g., the pixel sensor structure 200) includes forming a single-photon avalanche photodiode structure (e.g., the photodiode sensor structure 204) in a semiconductor layer (e.g., the semiconductor layer 206). The series of semiconductor processing operations includes forming an optical spacer structure (e.g., the optical spacer structure 212) that is transmissive to near infrared light over the semiconductor layer. The series of semiconductor processing operations includes forming a lens structure (e.g., the lens structure 214) that is transmissive to near infrared light on the optical spacer structure and over the single-photon avalanche photodiode structure.

As indicated above, FIGS. 4A-4I are provided as an example. Other examples may differ from what is described with regard to FIGS. 4A-4I.

Using features described in connection with FIGS. 2A-2D, 3, and 4A-4I, one or more advantages may be realized that improve a performance of a pixel sensor structure in a low lighting application. For example, and in contrast to another pixel sensor structure not including a lens structure with a convex surface, the pixel sensor structure 200 including the lens structure 214 having the convex surface 216 may redirect and increase an amount of the light 306 received by a sensing area of the photodiode sensor structure 204 to improve a quantum efficiency performance of the photodiode sensor structure 204 and/or a sensitivity performance of the pixel sensor structure 200.

Additionally, or alternatively and in contrast to another pixel sensor structure including a photodiode sensor structure with a reduced width, the pixel sensor structure 200 including the photodiode sensor structure 204 having the increased width D2 may have an increased sensing area to receive a larger amount of the light 306 to improve a quantum efficiency performance of the photodiode sensor structure 204 and/or a sensitivity performance of the pixel sensor structure 200.

Additionally, or alternatively and in contrast to another pixel sensor structure including a photodiode sensor structure with a reduced thickness, the pixel sensor structure 200 the photodiode sensor structure 204 having the increased thickness D3 may include more type III-V material having a direct bandgap that is suitable detecting individual photons to improve a quantum efficiency performance of the photodiode sensor structure 204 and/or a sensitivity performance of the pixel sensor structure 200.

Additionally, or alternatively and in contrast to another pixel sensor structure not including an anti-reflective coating layer on a convex surface of a lens structure, the pixel sensor structure 200 including the anti-reflective coating layer 218a on the convex surface 216 of the lens structure 214 may reduce an amount of light reflected from the convex surface 216 (e.g., the reflection 310a) and instead redirect the amount through the pixel sensor structure 200 to the photodiode sensor structure 204 to improve a quantum efficiency performance of the photodiode sensor structure 204 and/or a sensitivity performance of the pixel sensor structure 200.

Additionally, or alternatively and in contrast to another pixel sensor structure having a lens structure but not including the optical spacer structure 212, the optical spacer structure 212 in the pixel sensor structure 200 having the lens structure 214 may position the lens structure 214 such that an amount of the light 306 received and redirected by the lens structure 214 to the photodiode sensor structure 204 is increased. In other words, the optical spacer structure 212 may reposition a focal length of the lens structure 214 to increase an amount of the light 306 received the photodiode sensor structure 204 to improve a quantum efficiency performance of the photodiode sensor structure 204 and/or a sensitivity performance of the pixel sensor structure 200.

Additionally, or alternatively and in contrast to another pixel sensor structure not including an anti-reflective coating layer on a semiconductor layer, the pixel sensor structure 200 including the anti-reflective coating layer 218b on the semiconductor layer 206 may reduce an amount of light reflected from the semiconductor layer 206 (e.g., the reflection 310b) and instead redirect the amount through the pixel sensor structure 200 to the photodiode sensor structure 204 to improve a quantum efficiency performance of the photodiode sensor structure 204 and/or a sensitivity performance of the pixel sensor structure 200.

Additionally, or alternatively and in contrast to another pixel sensor structure not including an anti-reflective coating layer on a photodiode sensor structure, the pixel sensor structure including the anti-reflective coating layer 218c on the photodiode sensor structure 204 may reduce an amount of light reflected from the photodiode sensor structure 204 (e.g., the reflection 310b) and instead enable the photodiode sensor structure 204 to absorb the amount to improve a quantum efficiency performance of the photodiode sensor structure 204 and/or a sensitivity performance of the pixel sensor structure 200.

In one or more of these ways, a quantum efficiency performance of the photodiode sensor structure 204 and/or a sensitivity performance of the pixel sensor structure 200 is increased to satisfy one or more performance thresholds related to a low-light sensing application. By satisfying the one or more performance thresholds, an amount of resources supporting a volume of a market using the pixel sensor structure 200 (e.g., labor, raw materials, semiconductor processing tools, and/or computing resources that are consumed achieving a manufacturing yield that corresponds to the one or more performance thresholds) is reduced.

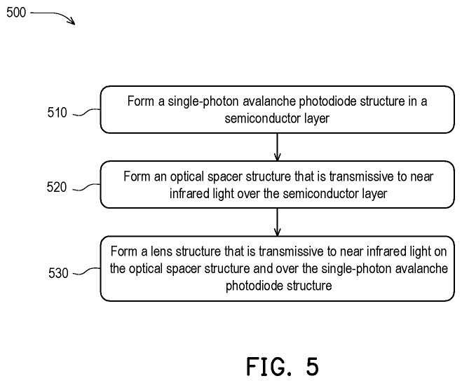

FIG. 5 is a flowchart of an example process 500 associated with forming a pixel sensor structure described herein. In some implementations, one or more process blocks of FIG. 5 are performed using one or more semiconductor processing tools referenced in connection with FIGS. 4A-4I. Additionally, or alternatively, one or more process blocks of FIG. 5 may be performed using another device or a group of devices separate from or including the one or more of the semiconductor processing tools, such as processing tools that may be included in semiconductor foundry, a wafer fabrication facility, an image sensor fabrication facility, or a lens fabrication facility.

As shown in FIG. 5, process 500 may include forming a single-photon avalanche photodiode structure in a semiconductor layer (block 510). For example, one or more of the semiconductor processing tools 102-7 may be used to form a single-photon avalanche photodiode structure (e.g., the photodiode sensor structure 204) in a semiconductor layer (e.g., the semiconductor layer 206), as described herein.

As further shown in FIG. 5, process 500 may include forming a optical spacer structure that is transmissive to near infrared light over the semiconductor layer (block 520). For example, one or more of the semiconductor processing tools may be used to form a optical spacer structure (e.g., the optical spacer structure 212) that is transmissive to near infrared light over the semiconductor layer, as described herein.

As further shown in FIG. 5, process 500 may include forming a lens structure that is transmissive to near infrared light on the optical spacer structure and over the single-photon avalanche photodiode structure (block 530). For example, one or more of the semiconductor processing tools may be used to form a lens structure (e.g., the lens structure 214) that is transmissive to near infrared light on the optical spacer structure and over the single-photon avalanche photodiode structure, as described herein.

Process 500 may include additional implementations, such as any single implementation or any combination of implementations described below and/or in connection with one or more other processes described elsewhere herein.

In a first implementation, process 500 includes forming an anti-reflective coating layer (e.g., the anti-reflective coating layer 218c) in a cavity (e.g., the cavity 402) of the semiconductor layer prior to forming the single-photon avalanche photodiode structure. In some implementations, the cavity is used form the single-photon avalanche photodiode structure.

In a second implementation, alone or in combination with the first implementation, process 500 includes forming an anti-reflective coating layer (e.g., the anti-reflective coating layer 218b) on the semiconductor layer prior forming the optical spacer structure.

In a third implementation, alone or in combination with one or more of the first and second implementations, process 500 includes forming a multi-layer structure (e.g., the multi-layer structure 210) on the anti-reflective coating layer prior to forming the optical spacer structure. In some implementations, forming the multi-layer structure includes depositing at least one layer of a dielectric material that is transmissive to near infrared light over the anti-reflective coating layer.

In a fourth implementation, alone or in combination with one or more of the first through third implementations, forming the optical spacer structure includes depositing a layer of a polymer material over the semiconductor layer using a spin coating process.

In a fifth implementation, alone or in combination with one or more of the first through fourth implementations, forming the lens structure includes depositing a layer of a polymer material on the optical spacer structure using a spin coating process, and reflowing the layer of the polymer material to form a surface having a convex curvature (e.g., the convex surface 216) that extends away from the lens structure.

In a sixth implementation, alone or in combination with one or more of the first through fifth implementations, process 500 includes forming an anti-reflective coating layer (e.g., the anti-reflective coating layer 218a) on the surface having the convex curvature.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

Some implementations herein include a pixel sensor structure and methods of forming. The pixel sensor structure includes a lens structure, a photodiode sensor structure, and an optical spacer structure between the lens structure and the photodiode sensor structure. The lens structure redirects near infrared light through the optical spacer structure and to the photodiode sensor structure to improve the quantum efficiency performance of the photodiode sensor structure relative to another photodiode sensor structure include in a pixel sensor structure without the lens structure and the optical spacer structure. Additionally, different configurations of an anti-reflection coating layer may be included throughout the pixel sensor structure to improve the quantum efficiency performance of the photodiode sensor structure further.

In this way a quantum efficiency performance of the photodiode sensor structure and/or a sensitivity performance of the pixel sensor structure is increased to satisfy one or more performance thresholds related to an application that senses images in a low-lighting environment. By satisfying the one or more performance thresholds, an amount of resources supporting a volume of a market using the pixel sensor structure 200 (e.g., labor, raw materials, semiconductor processing tools, and/or computing resources that are consumed achieving a manufacturing yield that corresponds to the one or more performance thresholds) is reduced.

As described in greater detail above, some implementations described herein provide a pixel sensor structure. The pixel sensor structure includes a photodiode region having a photodiode sensor structure in a semiconductor layer. The pixel sensor structure includes a lens structure apart from the photodiode region and having a convex surface facing away from the photodiode region. The pixel sensor structure includes an optical spacer structure between the photodiode region and the lens structure. In some implementations, the optical spacer structure is configured to maintain a separation distance between a bottom of the lens structure and a top of the photodiode region.

As described in greater detail above, some implementations described herein provide a system. The system includes an image sensor device including a pixel sensor structure. The pixel sensor structure includes a lens structure, a single-photon avalanche photodiode structure, a multi-layer structure having an electrically conductive material that is transmissive to near infrared light between the lens structure and the single-photon avalanche photodiode structure, and at least one anti-reflective coating layer in a near infrared light path between a near infrared light source and the single-photon avalanche photodiode structure.

As described in greater detail above, some implementations described herein provide a method. The method includes forming a single-photon avalanche photodiode structure in a semiconductor layer. The method includes forming an optical spacer structure that is transmissive to near infrared light over the semiconductor layer. The method includes forming a lens structure that is transmissive to near infrared light on the optical spacer structure and over the single-photon avalanche photodiode structure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel sensor structure, comprising:
a photodiode region having a photodiode sensor structure in a semiconductor layer;
a lens structure apart from the photodiode region and having a substantially convex surface facing away from the photodiode region; and
an optical spacer structure between the photodiode region and the lens structure,
wherein the optical spacer structure is configured to maintain a separation distance between a bottom of the lens structure and a top of the photodiode region.

2. The pixel sensor structure of claim 1, further comprising:
a multi-layer structure between the semiconductor layer and the lens structure,
wherein the optical spacer structure is on the multi-layer structure.

3. The pixel sensor structure of claim 2, wherein the multi-layer structure comprises at least one layer of an electrically conductive material that is transmissive to near infrared light.

4. The pixel sensor structure of claim 1, further comprising:
a first isolation structure and a second isolation structure on opposite sides of the photodiode sensor structure,
wherein the optical spacer structure is between the first and second isolation structures and the lens structure.

5. The pixel sensor structure of claim 1, wherein a ratio of a radius of curvature of the lens structure to a width of the photodiode sensor structure is included in a range of approximately 2:5 to approximately 3:5.

6. The pixel sensor structure of claim 1, wherein a thickness of the photodiode sensor structure is greater than or equal to approximately 3 microns.

7. The pixel sensor structure of claim 1 wherein one or more of the lens structure or the optical spacer structure includes a polymer material, comprising:
polymethyl methacrylate,
polycarbonate,
polyethylene, or
polyvinylidene fluoride.

8. The pixel sensor structure of claim 1 wherein one or more of the lens structure or the optical spacer structure includes a resin material, comprising:
epoxy resin.

9. The pixel sensor structure of claim 1, wherein one or more of the lens structure or the optical spacer structure includes an organic material, comprising:
a cyclo-olefin copolymer, or
a cyclo-olefin polymer.

10. A system, comprising:
an image sensor device, comprising:
a pixel sensor structure, comprising:
a lens structure;
a single-photon avalanche photodiode structure;
a multi-layer structure having an electrically conductive material that is transparent to near infrared light between the lens structure and the single-photon avalanche photodiode structure; and
at least one anti-reflective coating layer in a near infrared light path between a near infrared light source and the single-photon avalanche photodiode structure.

11. The system of claim 10, wherein the at least one anti-reflective coating layer comprises:
an anti-reflective coating layer on a substantially convex surface of the lens structure.

12. The system of claim 10, wherein the single-photon avalanche photodiode structure is embedded in a silicon layer, and wherein the at least one anti-reflective coating layer comprises:
an anti-reflective coating layer on the silicon layer and between the multi-layer structure and the single-photon avalanche photodiode structure.

13. The system of claim 10, wherein the at least one anti-reflective coating layer comprises:
an anti-reflective coating layer on the single-photon avalanche photodiode structure and between the multi-layer structure and the single-photon avalanche photodiode structure.

14. A method, comprising:
forming a single-photon avalanche photodiode structure in a semiconductor layer;
forming a optical spacer structure that is transmissive to near infrared light over the semiconductor layer; and
forming a lens structure that is transmissive to near infrared light on the optical spacer structure and over the single-photon avalanche photodiode structure.

15. The method of claim 14, further comprising:
forming an anti-reflective coating layer in a cavity of the semiconductor layer prior to forming the single-photon avalanche photodiode structure,
wherein the cavity is used form the single-photon avalanche photodiode structure.

16. The method of claim 14, further including:
forming an anti-reflective coating layer on the semiconductor layer prior forming the optical spacer structure.

17. The method of claim 16, further including:
forming a multi-layer structure on the anti-reflective coating layer prior to forming the optical spacer structure,
wherein forming the multi-layer structure includes depositing at least one layer of a dielectric material that is transmissive to near infrared light over the anti-reflective coating layer.

18. The method of claim 14, wherein forming the optical spacer structure includes:
depositing a layer of a polymer material over the semiconductor layer using a spin coating process.

19. The method of claim 14, wherein forming the lens structure includes:
depositing a layer of a polymer material on the optical spacer structure using a spin coating process, and
reflowing the layer of the polymer material to form a surface having a convex curvature that extends away from the lens structure.

20. The method of claim 19, further including:
forming an anti-reflective coating layer on the surface having the convex curvature.
